(19) United States
(12) Patent Application Publication
(10) Pub. No.: US 2025/0379120 A1
(43) Pub. Date: Dec. 11, 2025

(54) SEMICONDUCTOR PACKAGE INCLUDING HEAT TRANSFER MEMBER

(71) Applicant: SAMSUNG ELECTRONICS CO., LTD., SUWON-SI (KR)

(72) Inventors: Yeonghyeon Gim, Suwon-si (KR); Sounguk Kim, Suwon-si (KR); Minwoo Cho, Suwon-si (KR)

(21) Appl. No.: 19/079,127

(22) Filed: Mar. 13, 2025

(30) Foreign Application Priority Data
Jun. 7, 2024 (KR) 10-2024-0074176

(51) Int. Cl. H01L 23/433; H01L 21/48; H01L 23/00; H01L 23/367; H01L 23/373

(52) U.S. Cl. CPC H01L 23/433; H01L 23/3677; H01L 23/3735; H01L 24/32; H01L 21/4875; H01L 24/16; H01L 24/73; H01L 2224/16227; H01L 2224/32225; H01L 2224/32245; H01L 2224/73204; H01L 2224/73253; H01L 2924/1431

(57) ABSTRACT

A semiconductor package may include a package substrate having an upper surface and a lower surface facing each other; a semiconductor device mounted on the package substrate and providing a front surface and a backside surface; a heat slug disposed on an edge region of the upper surface of the package substrate and the backside surface of the semiconductor device; and a heat transfer member disposed between the package substrate and the heat slug, and surrounding side portions of the semiconductor device, wherein the heat transfer member includes a body portion having an elastic material; and a thermal conductive film covering the body portion.

### CROSS-REFERENCE TO RELATED APPLICATION

This application claims priority under 35 U.S.C. §119 to Korean Patent Application No. 10-2024-0074176, filed on Jun. 7, 2024, in the Korean Intellectual Property Office (KIPO), the disclosure of which is herein incorporated by reference in its entirety.

### BACKGROUND

### 1. Technical Field

Example embodiments of the present disclosure relate to a semiconductor package including a heat transfer member. More particularly, example embodiments relate to a semiconductor package including a resilient heat dissipation member.

### 2. Discussion of Related Art

Semiconductor devices generate heat during operation. These semiconductor devices may be employed in a semiconductor package. Heat generated from the semiconductor device may be dissipated to the outside of the semiconductor package through portions which are in contact with the semiconductor package. Effective heat dissipation from the semiconductor package may improve device efficiency, reliability, and longevity. A heat dissipation member including metallic material may be applied for improving heat performance of the semiconductor package. For example, a heat slug for covering a semiconductor device may be used as the heat dissipation member.

### SUMMARY

Example embodiments provide a semiconductor package having improved thermal performances.

According to example embodiments, a semiconductor package includes a package substrate having an upper surface and a lower surface facing each other; a semiconductor device mounted on the package substrate and providing a front surface and a backside surface; a heat slug disposed on an edge region of the upper surface of the package substrate and the backside surface of the semiconductor device; and a heat transfer member disposed between the package substrate and the heat slug, and surrounding side portions of the semiconductor device, wherein the heat transfer member includes a body portion having an elastic material; and a thermal conductive film covering the body portion.

According to example embodiments, a semiconductor package includes a package substrate providing an inner region and an edge region surrounding the inner region; a semiconductor device mounted on the inner region of the package substrate; a heat slug including a first portion provided on the semiconductor device, a second portion provided on the edge region of the package substrate, and an inclined portion connecting the first portion and the second portion; and a heat transfer member provided on the inner region of the package substrate and disposed between the semiconductor device and the inclined portion, wherein the heat transfer member includes a body portion having an elastic material and disposed on the inner region of the package substrate proximate to side portions of the semiconductor device; and a thermal conductive film covering the body portion.

According to example embodiments, a semiconductor package includes a package substrate; a semiconductor device mounted on the package substrate; a heat slug including a first portion provided on the semiconductor device, a second portion provided on a portion of the package substrate, and an inclined portion connecting the first portion and the second portion; an adhesive member provided between an upper surface of the semiconductor device and a lower surface of the first portion of the heat slug and including thermal interface material (TIM); and a heat transfer member disposed in an internal space defined by an upper surface of the package substrate, side portions of the semiconductor device, and an inner surface of the inclined portion, the heat transfer member including a body portion having an elastic material and a thermal conductive film covering the body portion, the heat transfer member provided in the internal space to be in contact with the semiconductor device and the heat slug, wherein the heat transfer member provides a first surface in contact with the side portions of the semiconductor device and a second surface in contact with the heat slug.

According to example embodiments, a method of manufacturing a semiconductor package, comprising: providing a package substrate having an upper surface and a lower surface; mounting a semiconductor device on the package substrate, the semiconductor device providing a front surface and a backside surface; providing a heat transfer member on the package substrate and surrounding side portions of the semiconductor device, wherein the heat transfer member includes, a body portion having an elastic material, and a thermal conductive film covering the body portion; and attaching a heat slug on an edge region of the upper surface of the package substrate, the heat transfer member, and the backside surface of the semiconductor device.

According to example embodiments, the attaching of the heat slug compresses the heat transfer member. According to example embodiments, the attaching of the heat slug changes a shape of the heat transfer member.

According to example embodiments, a semiconductor package may include a package substrate, a semiconductor device mounted on the package substrate, a heat slug covering the package substrate and the semiconductor device, and a heat transfer member provided between the semiconductor device and the heat slug.

The heat transfer member may be in contact with the semiconductor device and the heat slug to cover side portions of the semiconductor device.

Accordingly, the heat transfer member may be disposed in a compressed state between the semiconductor device and the heat slug, and heat generated from the semiconductor device may be transferred to the heat slug through the heat transfer member. Accordingly, the heat generated from the semiconductor device may be released (or dissipated) to the outside of the semiconductor package through a relatively wide surface area of the heat slug, which may improve thermal performance of the semiconductor package.

### BRIEF DESCRIPTION OF THE DRAWINGS

FIG. 1 is a plan view illustrating a semiconductor package in accordance with example embodiments.

FIG. 2 is a cross-sectional view taken along the line A-A′ in FIG. 1.

FIG. 3 is a perspective view illustrating the semiconductor package of FIG. 1.

FIG. 4 is a plan view illustrating a heat transfer member in accordance with example embodiments.

FIG. 5 is a cross-sectional view illustrating a path through which heat is released in the semiconductor package of FIG. 1.

FIGS. 6 to 16 are views illustrating a method of manufacturing a semiconductor package in accordance with example embodiments.

FIG. 17 is a perspective view illustrating a semiconductor package in accordance with example embodiments.

FIG. 18 is a plan view illustrating the heat transfer member of FIG. 17.

FIG. 19 is a perspective view illustrating a semiconductor package in accordance with example embodiments.

FIG. 20 is a plan view illustrating the heat transfer member of FIG. 19.

### DETAILED DESCRIPTION

Hereinafter, example embodiments will be explained in detail with reference to the accompanying drawings. In the drawings, like numerals refer to like elements throughout. Repetitive descriptions of one or more elements may be omitted.

In example embodiments, a heat transfer member formed of an elastic material may be disposed in a compressed state between a semiconductor device and a heat slug, and heat generated from the semiconductor device may be transferred to the heat slug through the heat transfer member. Accordingly, the heat generated from the semiconductor device may be released (or dissipated) to the outside of the semiconductor package through a relatively wide surface area of the heat slug, which may improve thermal performance of the semiconductor package.

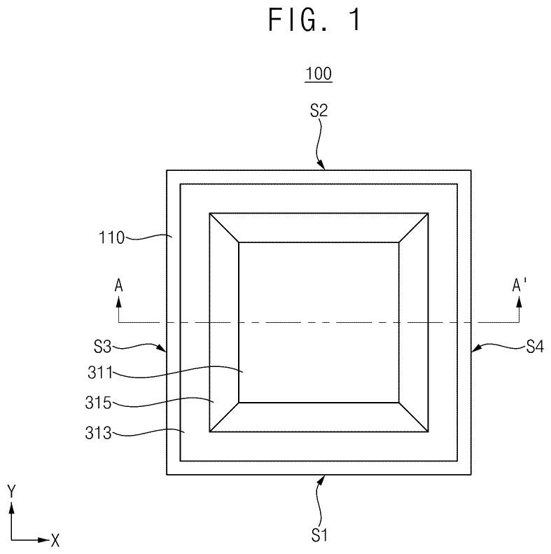

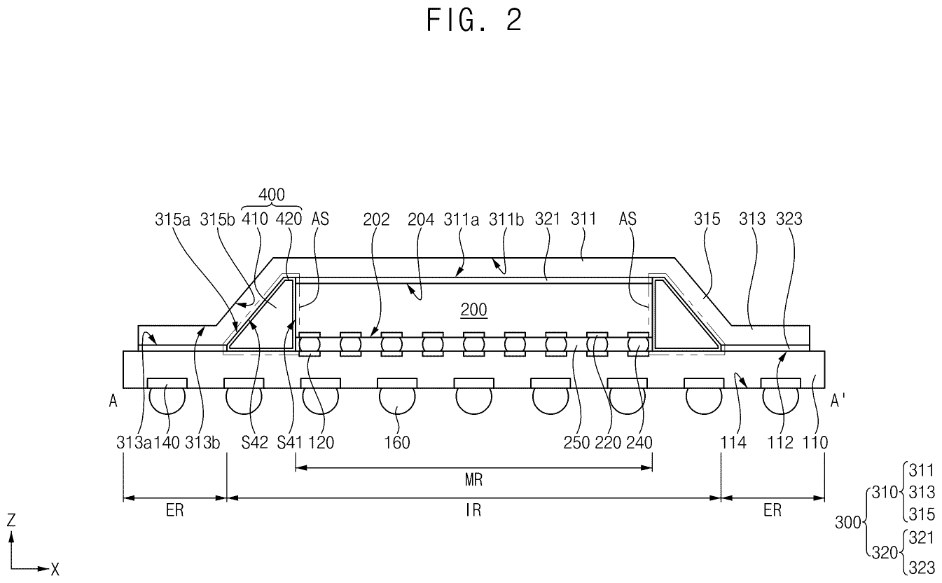

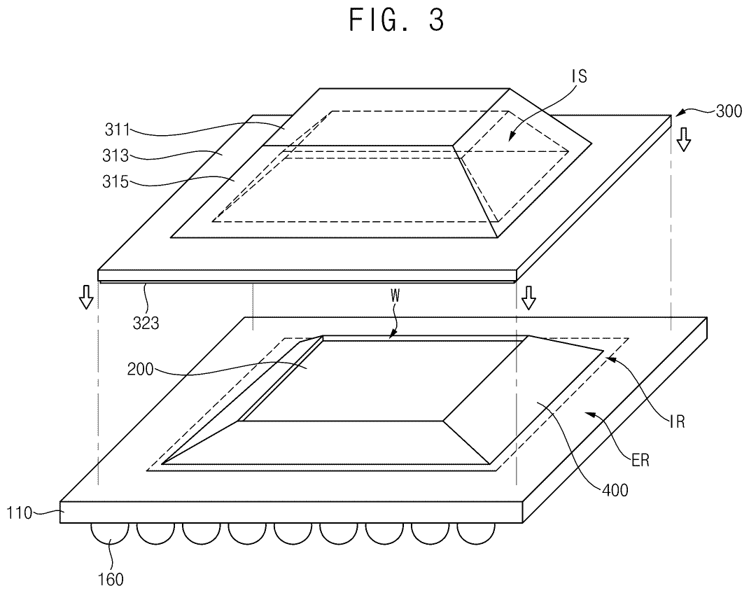

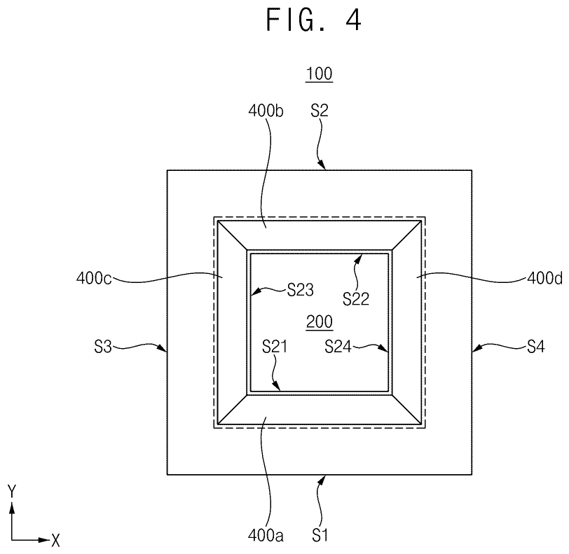

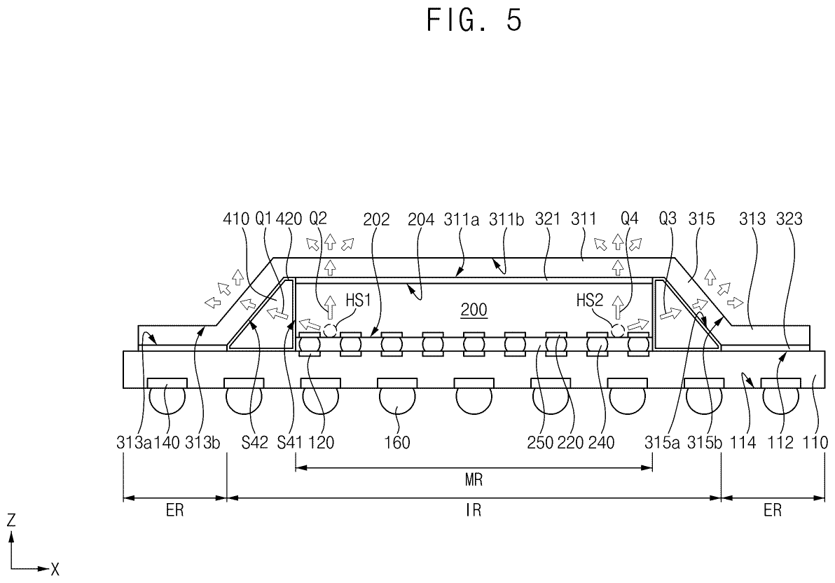

FIG. 1 is a plan view illustrating a semiconductor package in accordance with example embodiments. FIG. 2 is a cross-sectional view taken along the line A-A′ in FIG. 1. FIG. 3 is a perspective view illustrating the semiconductor package of FIG. 1. FIG. 4 is a plan view illustrating a heat transfer member in accordance with example embodiments. FIG. 5 is a cross-sectional view illustrating a path through which heat may be released in the semiconductor package of FIG. 1.

Referring to FIGS. 1 to 5, a semiconductor package 100 may include a package substrate 110, a semiconductor device 200, a heat dissipation member 300, and a first heat transfer member 400. The semiconductor device 200 may be mounted on the package substrate 110. The heat dissipation member 300 may cover the package substrate 110 and the semiconductor device 200. The first heat transfer member 400 may be provided between the semiconductor device 200 and the heat dissipation member 300.

In example embodiments, the package substrate 110 may include an upper surface 112 and a lower surface 114 facing the upper surface 112. The package substrate 110 may include a plurality of first substrate pads 120, a plurality of second substrate pads 140, and a plurality of external connection members 160. The plurality of first substrate pads 120 may be provided on the upper surface 112 of the package substrate 110. The plurality of second substrate pads 140 may be provided on the lower surface 114 of the package substrate 110. The plurality of external connection members 160 may be provided on the plurality of second substrate pads 140. For example, the plurality of first substrate pads 120, the plurality of second substrate pads 140, and the plurality of external connection members 160 may include a conductive material, such as a metal or metal alloy.

The package substrate 110 may include an inner region IR located at a center portion and an edge region ER proximate to the inner region IR. For example, the edge region ER may surround the inner region IR.

The inner region IR of the package substrate 110 may include a mounting region MR. A plurality of first substrate pads 120 may be disposed on the mounting region MR. Each of the plurality of first substrate pads 120 may be at least partially exposed from the upper surface 112. For example, the mounting region may have a rectangular shape when viewed in a plan view. The mounting region MR may be a region for mounting the semiconductor device 200.

The edge region ER of the package substrate 110 may be spaced apart from the mounting region MR along a horizontal direction such that the edge region ER may be disposed to surround the mounting region MR. For example, the package substrate 110 may include a first substrate side portion S1 and a second substrate side portion S2 facing the first substrate side portion S1. The first substrate side portion S1 and the second substrate side portion S2 may be parallel to each other and may extend in a first horizontal direction (X direction). Further, the package substrate 110 may include a third substrate side portion S3 and a fourth substrate side portion S4 facing the third substrate side portion S3. The third substrate side portion S3 and the fourth substrate side portion S4 may be parallel to each other and may extend in a second horizontal direction (Y direction) perpendicular to the first horizontal direction (X direction). The edge region ER may be arranged to surround the mounting region MR along the first to fourth substrate side portions S1, S2, S3, S4 of the package substrate 110.

The package substrate may include a plurality of internal wirings. The internal wirings may be provided within the package substrate to electrically connect the plurality of first substrate pads, the plurality of second substrate pads, and the plurality of external connection members. While certain substrate pads are illustrated in the figures, it will be understood that the number, shape, and arrangement of the substrate pads are provided as an example, and the present inventive concept is not limited thereto.

In example embodiments, the semiconductor device 200 may have a front surface 202 and a backside surface 204 facing the front surface 202. The semiconductor device 200 may be mounted on the mounting region MR of the package substrate 110 such that the front surface 202 faces the package substrate 110. For example, the front surface 202 may be an active surface on which a plurality of electronic elements are formed, and the backside surface 204 may be an inactive surface.

The semiconductor device 200 may be a single semiconductor chip or a semiconductor package including a plurality of semiconductor chips. For example, the semiconductor device 200 may include a logic chip having a logic circuit. In a case that the semiconductor device 200 is a semiconductor package including a plurality of semiconductor chips, the semiconductor chips may be arranged proximate to each other and/or in a stacked arrangement. Alternatively, the semiconductor device 200 may include a volatile memory device, such as DRAM, or a non-volatile memory device, such as NAND flash memory.

The semiconductor device 200 may include a plurality of chip pads 220, a plurality of conductive connection members 240, and an underfill member 250. The plurality of chip pads 220 may be provided on the front surface 202 of the semiconductor device 200. The plurality of conductive connection members 240 may be respectively provided on the plurality of chip pads 220. The underfill member 250 may be provided on the front surface 202 covering the plurality of conductive connection members 240. For example, the plurality of chip pads 220 and the plurality of conductive connection members 240 may include a conductive material, such as a metal or metal alloy.

The semiconductor device 200 may be flip-chip mounted on the package substrate 110. For example, the semiconductor device 200 may be mounted on the package substrate 110 via a plurality of conductive connection members 240 respectively provided between a plurality of first substrate pads 120 and a plurality of chip pads 220.

The semiconductor device 200 may include a first side portion S21 and a second side portion S22 facing the first side portion S21. The first side portion S21 and the second side portion S22 may extend in the first horizontal direction (X direction). Further, the semiconductor device 200 may include a third side portion S23 and a fourth side portion S24 facing the third side portion S23. The third side portion S23 and the fourth side portion S24 may extend in the second horizontal direction (Y direction) perpendicular to the first horizontal direction (X direction). For example, the semiconductor device 200 may have a rectangular shape when viewed in a plan view. For example, the semiconductor device 200 may have a square shape when viewed in a plan view.

The underfill member 250 may be provided on the mounting region MR of the package substrate 110. The underfill member 250 may fill a gap between the package substrate 110 and the semiconductor device 200. The underfill member 250 may fill the gap between the upper surface 112 of the package substrate 110 and the front surface 202 of the semiconductor device 200 and may cover sidewalls each of the plurality of conductive connection members 240. For example, the underfill member 250 may be a material that is sufficiently fluid to cover the gap between the package substrate and the semiconductor device. The underfill member 250 may include, for example, an epoxy material, a silica filler, or a polymer material.

While a certain number of chip pads are illustrated in the figures, it will be understood that the number, shape, and arrangement of the chip pads are provided as an example, and that the present inventive concept is not limited thereto.

In example embodiments, the heat dissipation member 300 may further include a heat slug 310 and a heat adhesive member 320. The heat slug 310 may provide a thermal path from the semiconductor device 200 to the outside of the semiconductor package 100. The heat slug 310 may be provided on the semiconductor device 200 and the package substrate 110. The heat adhesive member 320 may be provided below the heat slug 310. The heat dissipation member 300 may be a structure for dissipating heat generated by the semiconductor device 200 to the outside of the semiconductor package 100, thereby reducing the temperature of the semiconductor package 100 or maintaining a relatively low temperature of the semiconductor package 100. The heat dissipation member may include a metallic material having a relatively high thermal conductivity. For example, the heat dissipation member may include a metallic material such as copper (Cu) or aluminum (Al).

The heat slug 310 may include a first portion 311 provided on the semiconductor device 200, a second portion 313 provided on the edge region ER of the package substrate 110, and an inclined portion 315 connecting the first portion 311 and the second portion 313. The heat slug may dissipate heat generated from the semiconductor device 200 to the outside of the semiconductor package 100, reducing the temperature of the semiconductor package 100 or maintaining a relatively low temperature of the semiconductor package 100. Further, the heat slug 310 may physically protect the semiconductor device 200 from a contaminant. Further, the heat slug 310 may reduce warpage of the semiconductor package 100. For example, the heat slug 310 may include a metallic material such as copper (Cu) or aluminum (Al).

The first portion 311 may include a first surface 311a and a second surface 311b facing the first surface 311a. The first surface 311a of the first portion 311 may be a surface disposed on the semiconductor device 200. For example, the first surface 311a of the first portion 311 may be a surface in contact with the semiconductor device 200. The second surface 311b of the first portion 311 may be an exposed surface that is exposed to the outside of the semiconductor package 100. The first portion 311 may have a shape corresponding to the backside surface 204 of the semiconductor device 200. For example, the first portion 311 may have a rectangular shape, when viewed in a plan view.

The second portion 313 may include a third surface 313a and a fourth surface 313b facing each other. The third surface 313a of the second portion 313 may be a surface in contact with the package substrate 110. The fourth surface 313b of the second portion 313 may be an exposed surface that is exposed to the outside of the semiconductor package 100. The second portion 313 may may be provided along a plurality of side portions S1, S2, S3, S4 of the package substrate 110 such that the second portion 313 may be spaced apart from the semiconductor device 200 along the horizontal direction to surround the semiconductor device 200.

The inclined portion 315 may have a first inclined surface 315a and a second inclined surface 315b facing each other. The first inclined surface 315a of the inclined portion 315 may be an inner surface facing the package substrate 110. The second inclined surface 315b of the inclined portion 315 may be an outer surface exposed to the outside of the semiconductor package 100. The inclined portion 315 may extend from an end portion of the first portion 311 to an end portion of the second portion 313 to connect the first portion 311 and the second portion 313. The inclined portion 315 may have an angle relative to the first portion 311 and the second portion 313 between about 20 and 90 degrees, and more particularly an angle of about 50 degrees. For example, the inclined portion 315 may surround the side portions S21, S22, S23, S24 of the semiconductor device 200.

The heat slug 310 may be disposed on a portion of the upper surface 112 of the package substrate 110 and on the backside surface 204 of the semiconductor device 200.

The heat slug 310 may define a receiving space IS between the heat slug 310 and the package substrate 110. The receiving space IS may be a space in which the semiconductor device 200 is housed (or accommodated). For example, the receiving space IS may be defined by an upper surface 112 of the package substrate 110, a first surface 311a of a first portion 311 of the heat slug 310, and a first inclined surface 315a of an inclined portion 315 of the heat slug 310.

The heat slug 310 may be disposed on the package substrate 110 such that the semiconductor device 200 may be disposed within the receiving space IS. The semiconductor device 200 may be mounted on the package substrate 110, stacked within the receiving space IS. The first portion 311, the second portion 313, and the inclined portion 315 of the heat slug 310 may cover at least a portion of the upper surface 112 of the package substrate 110. The first portion 311, the second portion 313, and the inclined portion 315 of the heat slug 310 may cover the upper surface 112 of the package substrate 110 and the semiconductor device 200. The heat slug may physically protect the semiconductor device 200 by sealing the receiving space IS from the outside of the semiconductor package.

The receiving space IS may include an interior space AS. The interior space AS may be an empty space provided between the package substrate 110, the semiconductor device 200, and the heat slug 310. For example, the interior space may be defined by the upper surface 112 of the package substrate 110, the side portions S21, S22, S23, S24 of the semiconductor device 200, and the first inclined surface 315a of the inclined portion 315 of the heat slug 310. In a case where the first surface 311a of the first portion 311 of the heat slug 310 extends in a horizontal direction beyond the side portions S21, S22, S23, S24 of the semiconductor device 200, the interior space may be further defined by a portion of the first surface 311a of the first portion 311 of the heat slug 310.

The heat adhesive member 320 may include a first adhesive member 321 and a second adhesive member 323. The first adhesive member 321 may be provided between the semiconductor device 200. The second adhesive member 323 may be provided between the package substrate 110 and the second portion 313 of the heat slug 310.

The first adhesive member 321 may be provided between the backside surface 204 of the semiconductor device 200 and the first surface 311a of the first portion 311 of the heat slug 310. For example, the first adhesive member 321 may include a thermal interface material (TIM). The thermal interface material may be a material for enhancing thermal conductivity between contact surfaces by facilitating heat transfer. Specifically, the thermal interface material may be a structure for transferring heat between components by closely fitting the components so that spaces between components may be reduced or eliminated. Alternatively, the first adhesive member may include a variety of adhesive materials such as an adhesive film, pad, grease, or gel.

The first adhesive member 321 may be disposed in the space between the semiconductor device 200 and the first portion 311 of the heat slug 310. For example, the first adhesive member 321 may sufficiently fill the space between the semiconductor device 200 and the first portion 311 of the heat slug 310 to facilitate a transfer of heat generated by the semiconductor device 200 to the first portion 311 of the heat slug 310.

The second adhesive member 323 may be disposed on the upper surface 112 of the package substrate 110. The second adhesive member 323 may be disposed between the upper surface 112 of the package substrate 110 and the third surface 313a of the second portion 313 of the heat slug 310. For example, the second adhesive member 323 may include a variety of adhesive materials, such as an adhesive film, pad, grease, or gel. Alternatively, the second adhesive member 323 may include a thermal interface material (TIM).

In example embodiments, the first heat transfer member 400 may include a body portion 410 and a thermal conductive film 420. The body portion 410 may be disposed in the internal space AS and the thermal conductive film 420 may surround the body portion 410. The body portion 410 may apply a force to the thermal conductive film 420 wrapped around the body portion 410 to thermally contact the thermal conductive film 420 with one or more surfaces forming the inner space AS. The first heat transfer member 400 may be disposed in the inner space AS. The first heat transfer member 400 may be a structure for filling the inner space AS for transferring heat generated by the semiconductor device 200 to the heat slug 310. For example, the first heat transfer member 400 may include a thermal foam gasket (TFG). The thermal foam gasket may have memory foam properties, including for example, resiliency, and may be a structure for transferring heat. The thermal foam gasket may include a center portion, corresponding to the body portion 410, having memory foam properties, and the thermal foam gasket may include a thermal conductive layer, corresponding to the thermal conductive film 420, having relatively high thermal conductivity, for example, higher than the body portion 410, and in contact with the semiconductor device. The memory foam property may be such that when an external force is applied to a particular object, the shape of the particular object changes according to the external force, and when the external force is released, the shape of the particular object returns to original shape of the particular object.

The first heat transfer member 400 may be disposed on the inner region IR of the package substrate 110 and may surround the side portions S21, S22, S23, S24 of the semiconductor device 200. The first heat transfer member 400 may include a window W penetrating a center portion of the first heat transfer member 400. For example, the first heat transfer member 400 may extend above the backside surface 204 of the semiconductor device 200 to define the window W at a center portion corresponding to the semiconductor device 200. The window W may have a shape corresponding to the semiconductor device 200 such that the first heat transfer member 400 may cover the side portions S21, S22, S23, S24 of the semiconductor device 200. For example, the first heat transfer member 400 may have an annular rectangle shape when viewed in a plan view.

The first heat transfer member 400 may have a first surface S41 disposed in contact with the side portions S21, S22, S23, S24 of the semiconductor device 200 and a second surface S42 disposed in contact with the heat slug 310. For example, the first surface S41 of the first heat transfer member 400 may be an inner surface in contact with the side portions S21, S22, S23, S24 of the semiconductor device 200. Further, the second surface S42 of the first heat transfer member 400 may be an outer surface disposed in contact with the inclined portion 315 of the heat slug 310. The second surface of the first heat transfer member 400 may be an inclined surface having an angle corresponding to the first inclined surface 315a of the inclined portion 315. Thus, the first heat transfer member 400 may transfer heat generated from the semiconductor device 200 to the heat slug 310.

The first heat transfer member 400 may include a first portion 400a, a second portion 400b, a third portion 400c, and a fourth portion 400d. The first portion 400a may cover a first side portion S21 of the semiconductor device 200 to extend along a first horizontal direction (X direction). The second portion 400b may cover a second side portion S22 of the semiconductor device 200 to extend along a second horizontal direction (X direction). The third portion 400c may cover a third side portion S23 of the semiconductor device 200 to extend along the second horizontal direction (Y direction). The fourth portion 400d may cover a fourth side portion S24 of the semiconductor device 200 to extend along the second horizontal direction (Y direction).

The body portion 410 may include an elastic material, which may extend a shape of the first heat transfer member 400. The body portion 410 may have a shape corresponding to the internal space AS. For example, the body portion 410 may include a memory foam core. The memory foam core may be a central portion having memory foam properties and may be a resilient material. For example, the body portion may include urethan foam or silicon foam. Thus, the body portion 410 may fill the internal space AS, which may be an empty space between the package substrate 110, the semiconductor device 200, and the heat slug 310. For example, the first heat transfer member 400 may be provided in the internal space AS disposed in a compressed state between the package substrate 110 and the heat dissipation member 300.

Further, the body portion 410 may fill the internal space AS to cover the side portions S21, S22, S23, S24 of the semiconductor device 200. For example, a height of a top surface of the body portion 410 may be equal to or greater than a height of the backside surface 204 of the semiconductor device 200.

The thermal conductive film 420 may be a thin coating layer covering an outer surface of the body portion 410. The thermal conductive film 420 may include a material with high thermal conductivity to transfer heat. For example, the thermal conductive film may include graphite, aluminum, or copper. The thermal conductive film 420 may define at least a portion of a heat transfer pathway from the semiconductor device 200, generally around the body portion 410, to the heat dissipation member 300.

Referring again to FIG. 5, a heat transfer pathway, where heat generated by the semiconductor device 200 may be dissipated to the outside of the semiconductor package, is illustrated. The heat transfer pathway is illustrative, and not limiting.

For example, the semiconductor device 200 may include a first heat source HS1 and a second heat source HS2, which have relatively high temperature, on a portion of the first surface 202, which may be the active surface of the semiconductor device 200.

For example, portions Q2 and Q4 of the heat generated by the first heat source HS1 and the second heat source HS2 may be heat transferred to the upper surface 204 of the semiconductor device 200 and dissipated to the outside of the semiconductor package via the first portion 311 of the heat slug 310.

Further, portions Q1 and Q3 of the heat generated by the first heat source HS1 and the second heat source HS2 may be heat transferred to the inclined portion 315 of the heat slug 310 via the first heat transfer member 400 in contact with the side portions S21, S22, S23 and S24 of the semiconductor device 200. Thus, portions Q1 and Q3 of the heat generated by the first heat source HS1 and the second heat source HS2 may be dissipated to the outside of the semiconductor package from the inclined portion 315 of the heat slug 310.

The heat generated by the semiconductor device 200 may be dissipated through the first portion 311 of the heat slug 310 and the inclined portion 315 of the heat slug 310, improving thermal performance of the semiconductor package.

Certain heat sources and heat transfer paths are illustrated in FIG. 5, but it will be appreciated that these are provided as an example, and the present inventive concept is not limited thereto. Accordingly, the heat sources and heat transfer paths of the semiconductor package can be varied. For example, the heat slug 310 may be replaced by a heat spreader and/or a heat sink, which may include a patterned or finned upper surface.

As described herein, a semiconductor package 100 may include a package substrate 110, a semiconductor device 200 mounted on the package substrate 110, a heat slug 310 covering the package substrate 110 and the semiconductor device 200, and a first heat transfer member 400 provided between the semiconductor device 200 and the heat slug 310.

The first heat transfer member 400 may facilitate the transfer of heat from the semiconductor device 200 to the heat slug 310. The first heat transfer member 400 may be in contact with the semiconductor device 200 and the heat slug 310 to surround side portions of the semiconductor device 200.

Accordingly, the first heat transfer member 400 may be disposed in a space between the semiconductor device 200 and the heat slug 310, and heat generated by the semiconductor device may be transferred to the heat slug 310 through the first heat transfer member 400. Thus, the heat generated by the semiconductor device 200 may be dissipated to the outside of the semiconductor package 100 through a relatively large area, greater than an area of the semiconductor device 200, thereby improving thermal performance of the semiconductor package 100.

Hereinafter, a method for manufacturing the semiconductor package 100 of FIG. 1 will be described.

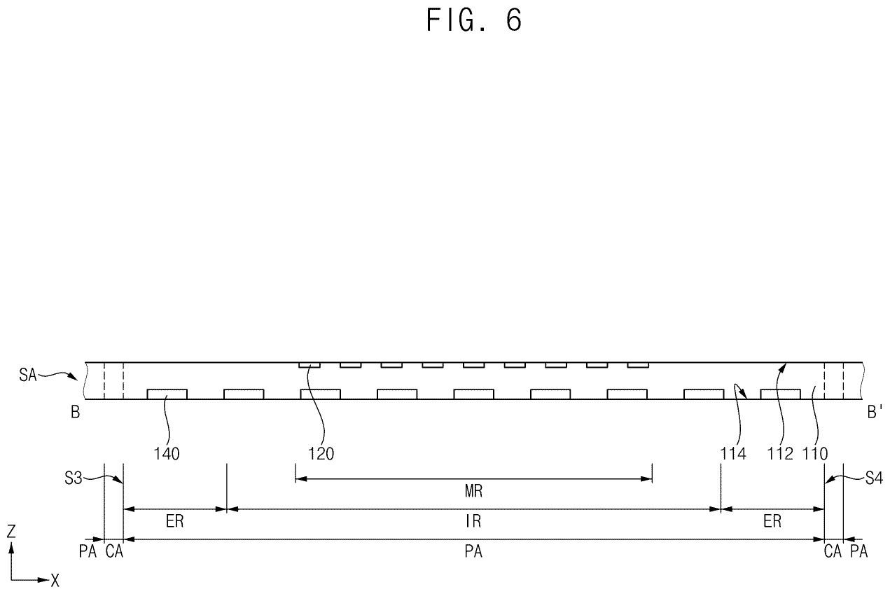

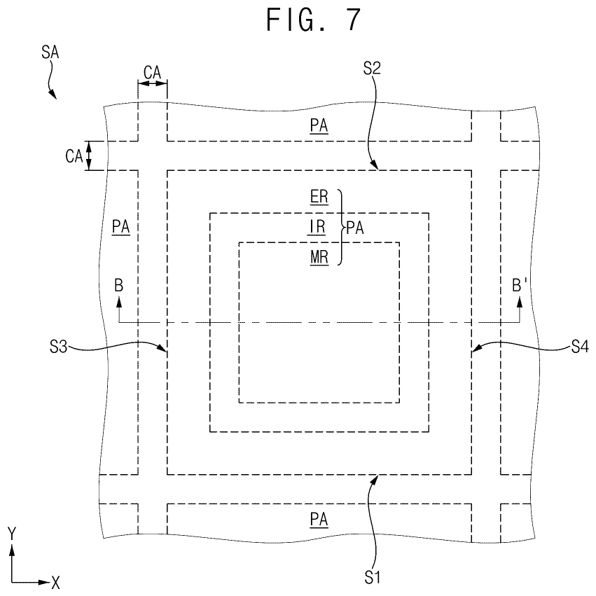

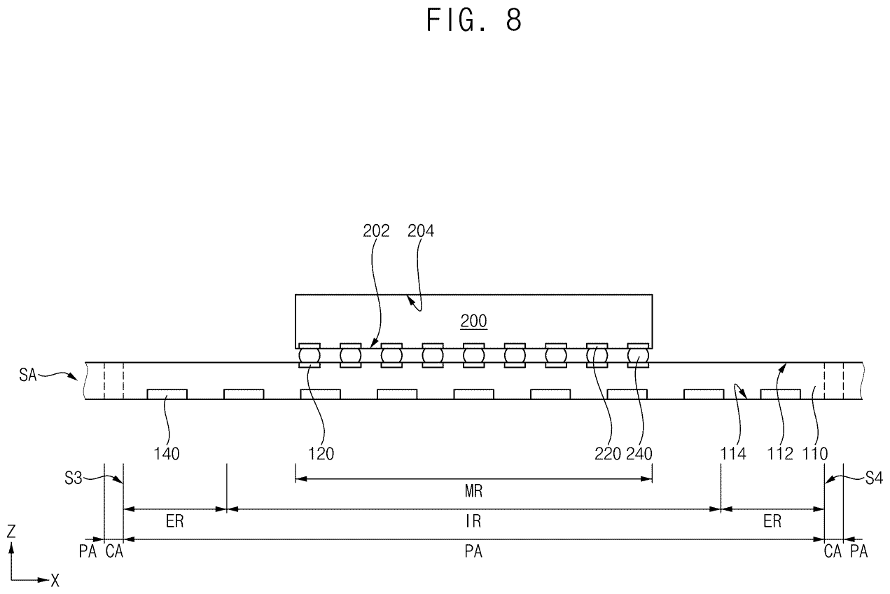

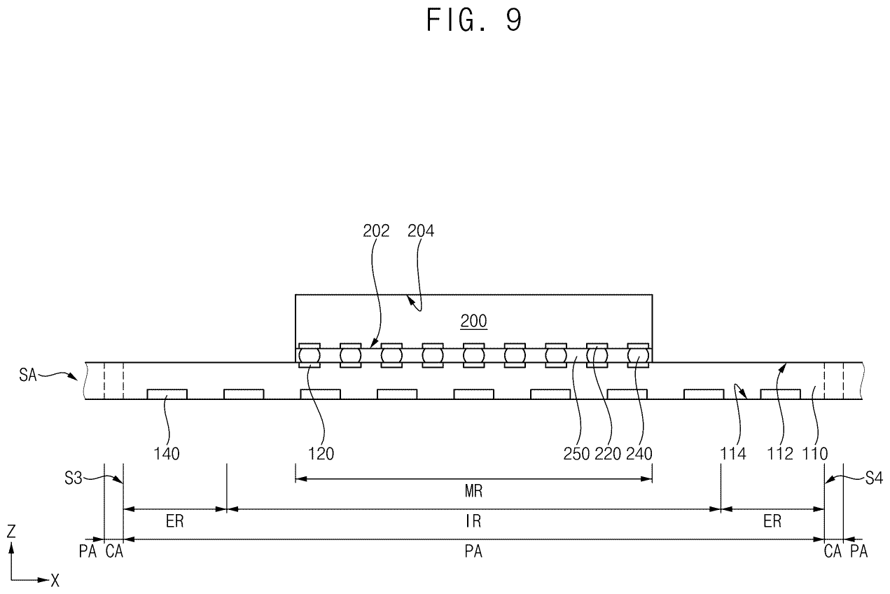

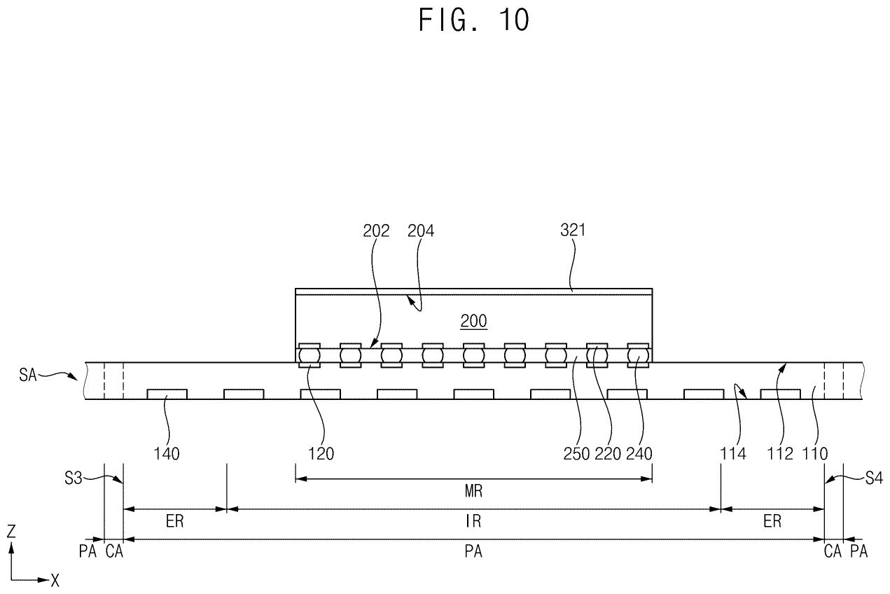

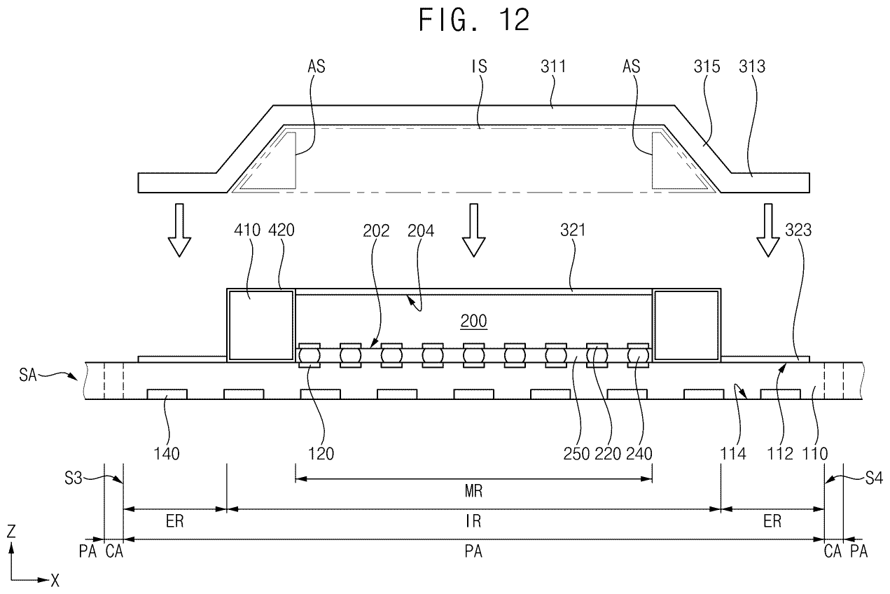

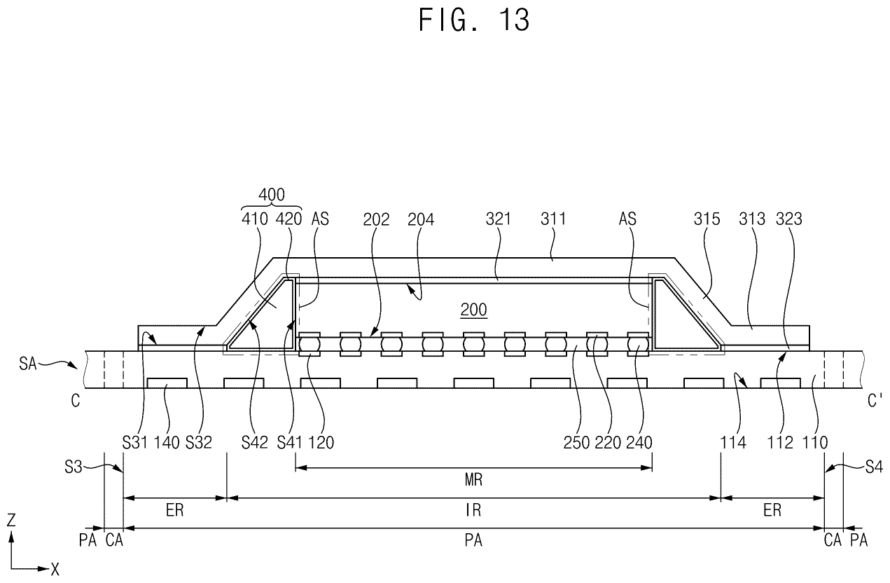

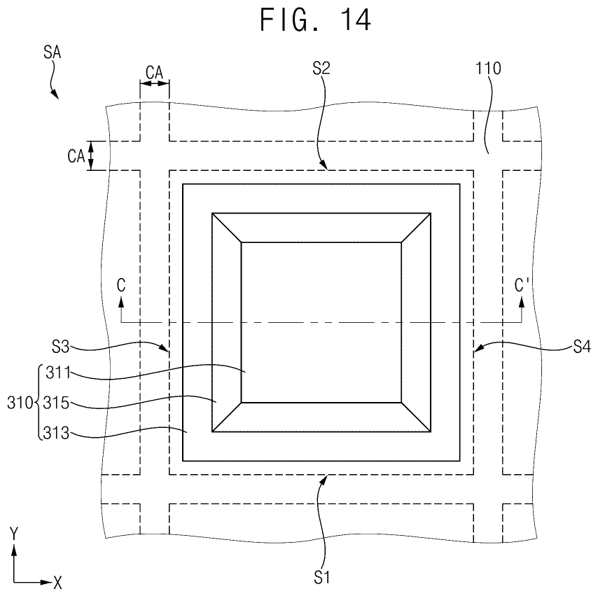

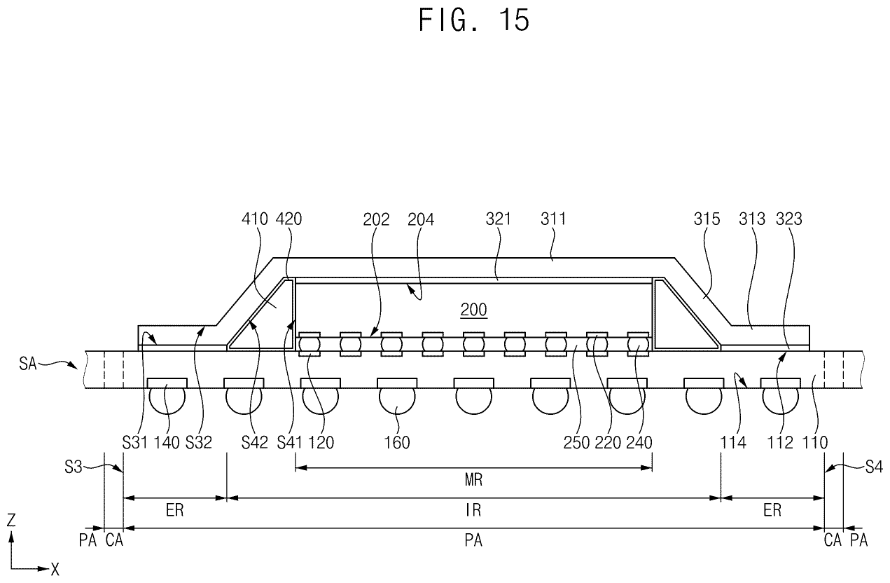

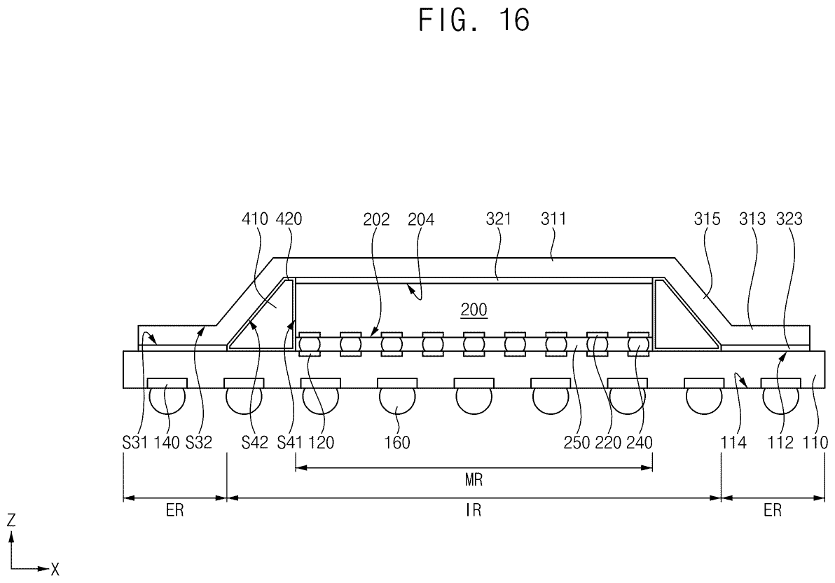

FIG. 6 is a cross-sectional view illustrating providing a substrate array. FIG. 7 is a plan view illustrating the substrate array of FIG. 6. FIG. 7 is a cross-sectional view taken along line B-B′ in FIG. 6. FIG. 8 is a cross-sectional view illustrating mounting a semiconductor device on the substrate array of FIG. 6. FIG. 9 is a cross-sectional view illustrating injecting an underfill member onto the substrate array of FIG. 8. FIGS. 10 to 14 are views illustrating attaching a heat dissipation member and a heat transfer member to the substrate array of FIG. 9. FIG. 13 is a cross-sectional view taken along line C-C′ in FIG. 14. FIG. 15 is a cross-sectional view illustrating attaching a plurality of external connection members to the substrate array of FIG. 13. FIG. 16 is a cross-sectional view illustrating individualizing the substrate array of FIG. 15 along the cutting region.

Since the semiconductor package manufactured by a manufacturing process illustrated in FIGS. 6 to 16 is substantially the same as the semiconductor package illustrated in FIGS. 1 to 5, the same components are denoted by the same reference numerals, and repeated descriptions of identical components may be omitted or simplified.

Referring to FIG. 6 and FIG. 7, a substrate array SA may be provided. The substrate array may include a plurality of package regions PA and a cutting region CA surrounding the plurality of package regions PA. Each package region PA may include a mounting region MR at a central portion. The package regions PA may be regions in which a semiconductor package may be formed by subsequent processes. Further, the cutting region CA may be region that may be removed to individualize the semiconductor package by subsequent processes.

Each of the plurality of package regions PA may include an inner region IR including the mounting region MR and an edge region ER surrounding the inner region IR.

The edge region ER may include a first side portion S1 and a second side portion S2 facing the first side portion S1, the first side portion S1 and the second side portion S2 extending along a first horizontal direction (X direction), and a third side portion S3 and a fourth side portion S4 facing to the third side portion S3, the third side portion S3 and the fourth side portion S4 extending along a second horizontal direction (Y direction). For example, the package region may have a rectangular shape when viewed in a plan view.

Referring to FIG. 8, a semiconductor device 200 may be respectively mounted on the mounting region MR of the substrate array SA. The semiconductor device 200 may have a front surface 202 and a backside surface 204 facing the front surface 202. The front surface 202 may be an active surface on which the plurality of electronic elements may be formed, and the backside surface 204 may be an inactive surface.

The semiconductor device 200 may be mounted such that the front surface 202 faces the substrate array SA. For example, the semiconductor device 200 may be flip-chip mounted on the package substrate 110. For example, the semiconductor device 200 may be mounted on the package substrate 110 via a plurality of conductive connection members 240 respectively provided between the plurality of first substrate pads 120 and the plurality of chip pads 220.

Referring to FIG. 9, an underfill material may be injected between the substrate array SA and the semiconductor device 200 to form an underfill member 250 that is disposed within the mounting region MR to covers sidewalls of the plurality of conductive connection members 240. For example, the underfill material may be a material that has sufficient fluidity to fill the gap between the package substrate and the semiconductor device. The underfill material may include an epoxy material.

Referring to FIGS. 10 to 14, a first adhesive member 321 may be attached to the semiconductor device 200, a first heat transfer member 400, including a body portion 410 and a thermal conductive film 420, may be attached to the package substrate 110 to surround the semiconductor device 200, and a heat slug 310 may be attached to the package region PA to cover the semiconductor device 200 and the first heat transfer member 400.

For example, the first adhesive member 321 may be attached to the backside surface 204 of the semiconductor device 200. For example, the first adhesive member 321 may be provided in the window W between the first portion 311 of the heat slug 310 and to the backside surface 204 of the semiconductor device 200.

The first heat transfer member 400 surrounding the side portions of the semiconductor device 200 may be positioned on the interior region IR of the package substrate 110. For example, the first heat transfer member 400 may be attached to the package substrate 110 by using an adhesive on a lower surface of the first heat transfer member 400. In this case, a height of the first heat transfer member 400 may be equal to or greater than a height of the semiconductor device 200. In example embodiments, the first heat transfer member 400 may be attached to the package substrate 110 prior to applying the first adhesive member 321 to the semiconductor device 200.

In example embodiments, the first heat transfer member 400 may include a body portion 410, which may be an elastic structure to change a shape of the body portion, and a thermal conductive film 420 surrounding the body portion 410. The first heat transfer member 400 may include a thermal foam gasket (TFG). The thermal foam gasket may be a structure having memory foam properties and relatively high thermal conductivity, for example, greater than a thermal conductivity of an air gap or a fill material.

The first heat transfer member 400 may be attached to the inner region IR of the package substrate 110 and may surround the side portions S21, S22, S23, S24 of the semiconductor device 200. For example, the first heat transfer member 400 may be attached to the package substrate 110 such that the semiconductor device 200 may be disposed within the window W (see FIG. 3) of the first heat transfer member 400.

A second adhesive member 323 may be attached to the edge region ER of the package substrate 110, and a heat slug 310 may be positioned on an upper portion of the package region PA of the package substrate 110. In an example embodiment, the second adhesive member 323 may be attached to the heat slug 310, and the heat slug 310 may be positioned on an upper portion of the package region PA of the package substrate 110.

In example embodiments, the heat slug 310 may include a first portion 311, a second portion 313, and an inclined portion 315 connecting the first portion 311 and the second portion 313. Further, the heat slug 310 may include an receiving space IS surrounded by the first surface 311a of the first portion 311 and the first inclined surface 315a of the inclined portion 315 (see FIG. 5). The first inclined surface 315a of the inclined portion 315 may be referred to as an inner surface. For example, the heat slug 310 may be positioned on the upper portion of the package region PA such that the receiving space IS faces the upper surface 112 of the package substrate 110.

The heat slug 310 may be moved downward along the vertical direction (Z direction) to attach the heat slug 310 to the package substrate 110 at the edge region ER of the package region PA and to the backside surface 204 of the semiconductor device 200. In this case, an external force may be applied to the first heat transfer member 400 by the heat slug 310. The first heat transfer member 400, being elastic, may be changed to have an inclined surface S42 corresponding to the inclined portion 315 of the heat slug 310. In an example embodiment, the substrate array SA may be moved upward along the vertical direction (Z direction) to attach the heat slug 310 to the package substrate 110 at the edge region ER of the package region PA and to the backside surface 204 of the semiconductor device 200.

For example, the heat slug 310 may be moved downward along the vertical direction (Z direction) so that the semiconductor device 200 may be inserted into the receiving space IS of the heat slug 310. The inclined portion 315 of the heat slug 310 may exert pressure on the upper surface of the first heat transfer member 400 to change the shape of the first heat transfer member 400.

Further, the first portion 311 of the heat slug 310 may be attached to the backside surface 204 of the semiconductor device 200, and the second portion 313 of the heat slug 310 may be attached to the edge region ER of the package region PA and the backside surface 204 of the semiconductor device 200. The inner space AS may be formed with the attachment of the heat slug 310 to the backside surface 204 of the semiconductor device 200 and the package substrate 110. The inner space AS may be defined by the upper surface 112 of the package substrate 110, the side portions S21, S22, S23, S24 of the semiconductor device 200, and the first inclined surface 315a of the inclined portion 315. And the first heat transfer member 400 may be positioned within the inner space AS.

Referring to FIG. 15, a plurality of external connection members 160 may be respectively attached to the plurality of second substrate pads 140 disposed on the lower surface 114 of the substrate array SA.

Referring to FIG. 16, a cutting process may be performed at the cutting regions CA of the substrate array SA, which may individualize the semiconductor package 100, which is formed on the package region PA. The cutting process may remove the cutting regions CA of the substrate array SA.

However, while the figures illustrate that the semiconductor device 200, the heat dissipation member 300, and the first heat transfer member 400 are mounted on a substrate array SA including a plurality of package regions PA and cutting region CA, it will be appreciated that this is provided as an example, and the present inventive concept is not limited thereto. Accordingly, the semiconductor device 200, the heat dissipation member 300, and the first heat transfer member 400 may be manufactured in such a way that the semiconductor device 200, the heat dissipation member 300, and the first heat transfer member 400 are mounted on a package substrate PA already individualized.

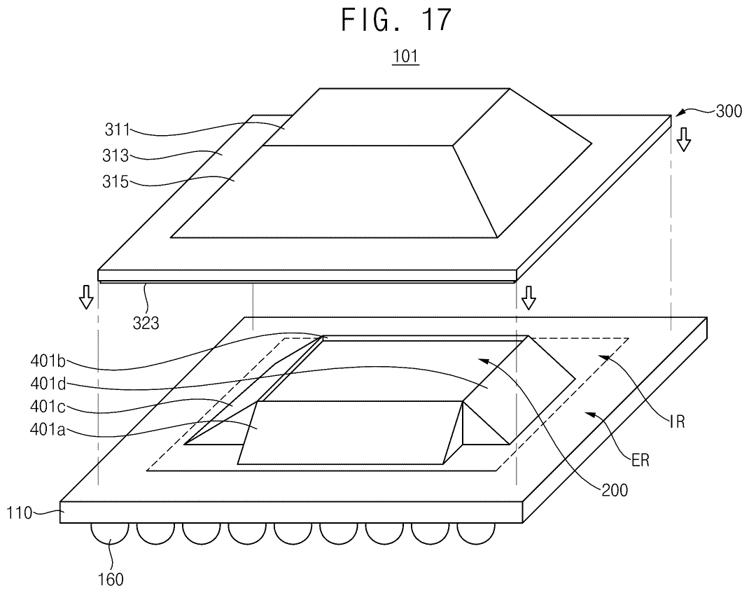

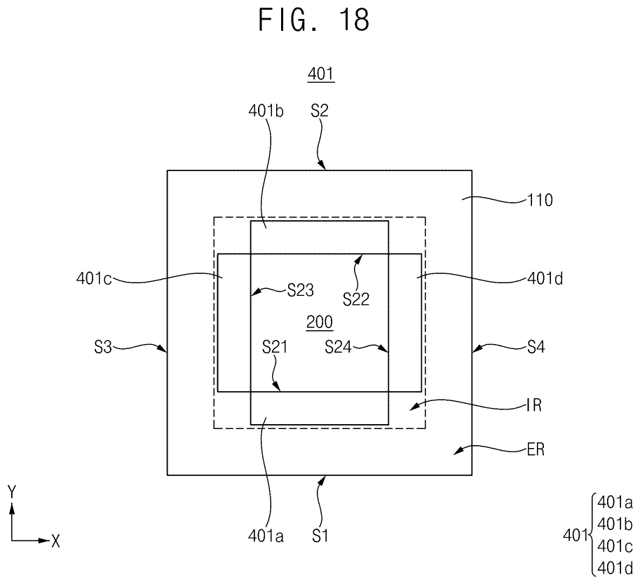

FIG. 17 is a perspective view illustrating a semiconductor package in accordance with example embodiments. FIG. 18 is a plan view illustrating the heat transfer member of FIG. 17.

The semiconductor package illustrated in FIG. 17 and FIG. 18 may be substantially the same as the semiconductor package illustrated in FIGS. 1 through 5, and the same components may be denoted by the same reference numerals and repeated descriptions of the components may be omitted or simplified. The semiconductor package illustrated in FIG. 17 and FIG. 18 may include a second heat transfer member 401.

Referring to FIG. 17 and FIG. 18, the semiconductor package 101 may include a package substrate 110, a semiconductor device 200 mounted on the package substrate 110, a heat dissipation member 300 covering the package substrate 110 and the semiconductor device 200, and a second heat transfer member 401 provided between the semiconductor device 200 and the heat dissipation member 300.

In example embodiments, the second heat transfer member 401 may include first to fourth lateral heat transfer members 401a, 401b, 401c, 401d. The second heat transfer member 401 may be a structure configured to fill at least a portion of the receiving space IS. The second heat transfer member 401 disposed in the receiving space IS may transfer heat generated by the semiconductor device 200 to the heat slug 310. For example, the second heat transfer member may include a thermal foam gasket (TFG).

Each of the first to fourth lateral heat transfer members 401a, 401b, 401c, and 401d may be provided on the inner region IR of the package substrate 110 to at least partially cover a side portion of the semiconductor device 200.

For example, the first lateral heat transfer member 401a may cover at least a portion of the first side portion S21 of the semiconductor device 200 and may extend along a first horizontal direction (X direction). The second lateral heat transfer member 401b may cover at least a portion of the second side portion S22 of the semiconductor device 200 and may extend along the first horizontal direction (X direction). The third lateral heat transfer member 401c may cover at least a portion of the third side portion S23 of the semiconductor device 200 and may extend along the second horizontal direction (Y direction). The fourth lateral heat transfer member 401d may cover at least a portion of the fourth side portion S24 of the semiconductor device 200 and may extend along the second horizontal direction (Y direction).

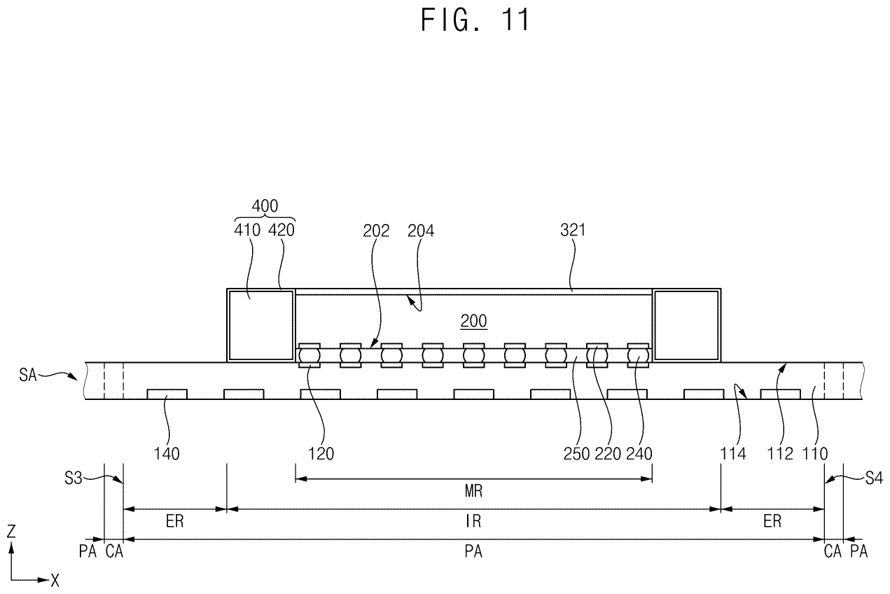

Each of the first to fourth lateral heat transfer members 401a, 401b, 401c, 401d may have a first surface S41 in contact with the semiconductor device 200 and a second surface S42 in contact with the heat slug 310 (see FIG. 16). Thus, each of the first to fourth lateral heat transfer members 401a, 401b, 401c, and 401d may fill the inner space AS disposed between the semiconductor device 200 and the heat slug 310. Each of the first to fourth lateral heat transfer members 401a, 401b, 401c, 401d may have a rectangle shape described in connection with FIG. 11 or a prism shape (see FIG. 17). In the case of a prism shape, each of the first to fourth lateral heat transfer members 401a, 401b, 401c, 401d may include an inclined upper surface. Each of the first to fourth lateral heat transfer members 401a, 401b, 401c, 401d may have a size that is equal to or larger than a size of the inner space AS. For example, in a case that each of the first to fourth lateral heat transfer members 401a, 401b, 401c, 401d is formed having a prism shape and is larger than a size of the inner space AS, the inclined portion 315 of the heat slug 310 may exert pressure on the inclined upper surface of the first heat transfer member 400 to change at least one or a shape or size of the first heat transfer member 400.

While certain lateral heat transfer members are illustrated in the figures, it will be understood that the number, shape, and arrangement of the lateral heat transfer members are provided as an example, and the present inventive concept is not limited thereto.

Each of the first to fourth lateral heat transfer members 401a, 401b, 401c and 401d may transfer heat generated by the semiconductor device 200 to the heat slug 310. Thus, the second heat transfer member 401 may improve thermal performance of the semiconductor package 101.

Further, the second heat transfer member 401 may include first to fourth lateral heat transfer members 401a, 401b, 401c and 401d. Accordingly, the second heat transfer member 401 may be manufactured without consideration of the shape of the semiconductor device 200, thereby increasing a process efficiency of manufacturing the semiconductor package.

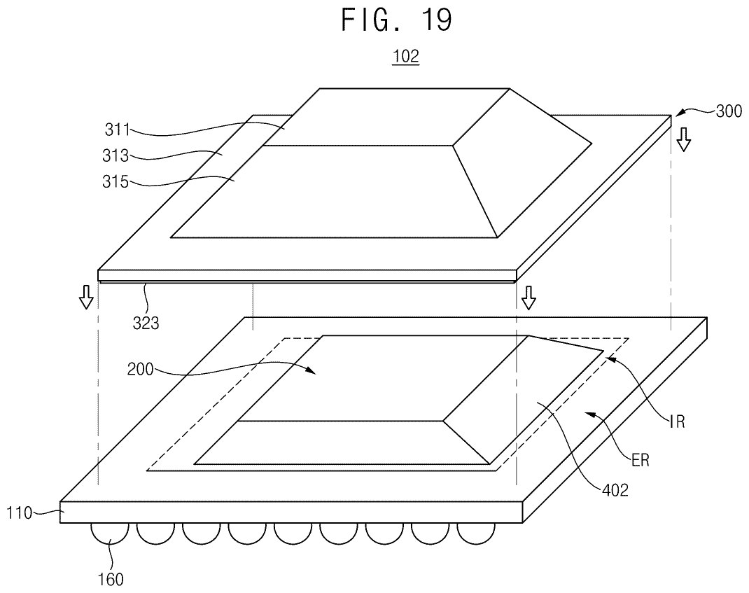

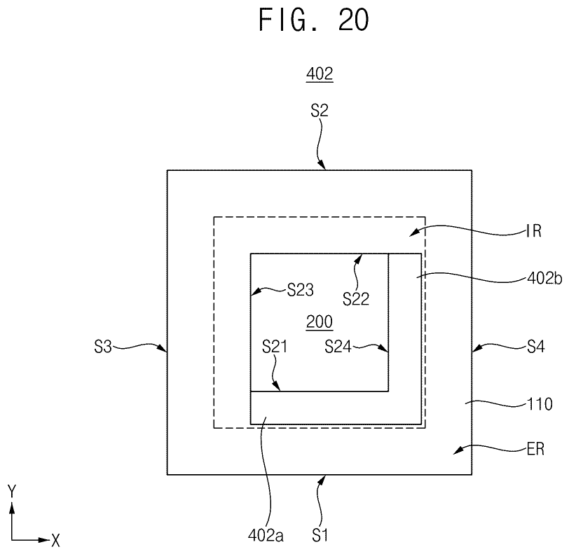

FIG. 19 is a perspective view illustrating a semiconductor package in accordance with example embodiments. FIG. 20 is a plan view illustrating the heat transfer member of FIG. 19.

The semiconductor package illustrated in FIG. 19 and FIG. 20 may be substantially the same as the semiconductor package illustrated in FIGS. 1 to 5, and the same components may be denoted by the same reference numerals and repeated descriptions of the components may be omitted or simplified. The semiconductor package illustrated in FIG. 19 and FIG. 20 may include a third heat transfer member 402.

Referring to FIG. 19 and FIG. 20, the semiconductor package 102 may include a package substrate 110, a semiconductor device 200 mounted on the package substrate 110, a heat dissipation member 300 covering the package substrate 110 and the semiconductor device 200, and a third heat transfer member 402 provided between the semiconductor device 200 and the heat dissipation member 300.

In example embodiments, the third heat transfer member 402 may be provided within the interior region IR of the package substrate 110 to cover two adjacent side portions of the semiconductor device 200. The third heat transfer member 402 may be a structure disposed in at least a portion of the interior space AS to transfer heat generated by the semiconductor device 200 to the heat slug 310. For example, the third heat transfer member may include a thermal foam gasket (TFG).

The third heat transfer member 402 may cover side portions S21 and S24 of the semiconductor device 200, the first side portion S21 and the fourth side portion S24 adjacent and perpendicular to each other. For example, the third heat transfer member 402 may include a first portion 402a extending in a first horizontal direction (X direction), and the third heat transfer member 402 may include a second portion 402b extending in a second horizontal direction (Y direction) perpendicular to the first horizontal direction (X direction) and adjacent to the first portion 402a. For example, the third heat transfer member may have an ‘L’ shape when viewed in a plan view. For example, the third heat transfer member 402 may expose the second side portion S22 and the third side portion S23. For example, the third heat transfer member 402 extends above the backside surface 204 of the semiconductor device 200 to define at least a portion of a window W at a center portion corresponding to the semiconductor device 200.

The third heat transfer member 402 may have a first surface S41 in contact with the semiconductor device 200 and a second surface S42 in contact with the heat slug 310 (see FIG. 16). Thus, the first portion 402a and the second portion 402b of the third heat transfer member 402 may be disposed in the inner space AS disposed between the semiconductor device 200 and the heat slug 310.

For example, the semiconductor device 200 may have a heat source having a relatively high temperature in an area adjacent to the first side portion S21 and the fourth side portion S24. In this case, the third heat transfer member 402 may transfer heat received from the first side portion S21 and the fourth side portion S24 of the semiconductor device 200 to the heat slug 310.

Thus, the third heat transfer member 402 may improve thermal performance of the semiconductor package 102.

Additionally, the third heat transfer member 402 may cover only a portion of the side portions of the semiconductor device 200, which may reduce a process costs.

Although the third heat transfer member 402 is illustrated in the figures as covering the first side portion S21 and the fourth side portion S24 of the semiconductor device 200, it will be appreciated that the present inventive concept is not limited thereto. Accordingly, location of the third heat transfer member 402 may vary, and may be disposed depending on location of the heat source. For example, a heat transfer member may include side portions disposed at two opposite side portions of the semiconductor device 200.

The semiconductor package may include semiconductor devices such as logic devices or memory devices. The semiconductor package may include logic devices such as central processing units (CPUs), main processing units (MPUs), or application processors (APs), volatile memory devices such as DRAM devices or HBM devices, or non-volatile memory devices such as flash memory devices, PRAM devices, MRAM devices, or ReRAM devices.

The foregoing is illustrative of example embodiments and is not to be construed as limiting thereof. Although example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a package substrate having an upper surface and a lower surface;
a semiconductor device mounted on the package substrate and providing a front surface and a backside surface;
a heat slug disposed on an edge region of the upper surface of the package substrate and the backside surface of the semiconductor device; and
a heat transfer member disposed between the package substrate and the heat slug, and surrounding side portions of the semiconductor device,
wherein the heat transfer member includes,
a body portion having an elastic material; and
a thermal conductive film covering the body portion.

2. The semiconductor package of claim 1, wherein the heat transfer member has a window at a center portion corresponding to the semiconductor device.

3. The semiconductor package of claim 1, wherein the heat transfer member is disposed in a compressed state between the package substrate and the heat slug and provides a first surface in contact with the semiconductor device and a second surface in contact with an inner surface of the heat slug.

4. The semiconductor package of claim 1, wherein the semiconductor device has a first side portion and a second side portion extending along a first horizontal direction, and a third side portion and a fourth side portion extending along a second horizontal direction perpendicular to the first horizontal direction, and
wherein the heat transfer member includes,
a first side heat transfer member at least partially covering the first side portion;
a second side heat transfer member at least partially covering the second side portion;
a third side heat transfer member at least partially covering the third side portion; and
a fourth side heat transfer member at least partially covering the fourth side portion.

5. The semiconductor package of claim 1, wherein the semiconductor device has a first side portion and a second side portion extending along a first horizontal direction, and a third side portion and a fourth side portion extending along a second horizontal direction perpendicular to the first horizontal direction, and
wherein the heat transfer member includes,
a first side heat transfer member at least partially covering the first side portion;
a fourth side heat transfer member at least partially covering the fourth side portion,
wherein the first side heat transfer member and the fourth side heat transfer member of the heat transfer member form an ‘L’ shape when viewed in a plan view such that the heat transfer member covers the first side portion and the fourth side portion of the semiconductor device, and
wherein the heat transfer member exposes the second side portion and the third side portion.

6. The semiconductor package of claim 1, wherein the body portion includes a memory foam core that is resilient, and the thermal conductive film includes a graphite.

7. The semiconductor package of claim 1, wherein the heat slug includes,
a first portion provided on the semiconductor device;
a second portion provided on the package substrate; and
an inclined portion connecting the first portion and the second portion and being in contact with the heat transfer member and surrounding the side portions of the semiconductor device.

8. The semiconductor package of claim 7, wherein an internal space is defined by the upper surface of the package substrate, the side portions of the semiconductor device, and an inner surface of the inclined portion, and the heat transfer member is disposed in the internal space.

9. The semiconductor package of claim 8, wherein the heat transfer member extends above the backside surface of the semiconductor device to define a window at a center portion corresponding to the semiconductor device, and
wherein the semiconductor package further includes an adhesive member provided in the window between the first portion of the heat slug and the semiconductor device and including thermal interface material (TIM).

10. A semiconductor package, comprising:
a package substrate providing an inner region and an edge region surrounding the inner region;
a semiconductor device mounted on the inner region of the package substrate;
a heat slug including a first portion provided on the semiconductor device, a second portion provided on the edge region of the package substrate, and an inclined portion connecting the first portion and the second portion; and
a heat transfer member provided on the inner region of the package substrate and disposed between the semiconductor device and the inclined portion,
wherein the heat transfer member includes,
a body portion having an elastic material and disposed on the inner region of the package substrate proximate to side portions of the semiconductor device; and
a thermal conductive film surrounding the body portion.

11. The semiconductor package of claim 10, wherein the heat transfer member has a window at a center portion corresponding to the semiconductor device such that the heat transfer member surrounds the side portions of the semiconductor device.

12. The semiconductor package of claim 11, wherein the heat transfer member provides a first surface in contact with the side portions of the semiconductor device and a second surface in contact with an inner surface of the inclined portion of the heat slug.

13. The semiconductor package of claim 10, wherein the semiconductor device has a first side portion and a second side portion extending along a first horizontal direction and a third side portion and a fourth side portion extending along a second horizontal direction perpendicular to the first horizontal direction,
wherein the heat transfer member includes,
a first side heat transfer member at least partially covering the first side portion;
a second side heat transfer member at least partially covering the second side portion;
a third side heat transfer member at least partially covering the third side portion; and
a fourth side heat transfer member at least partially covering the fourth side portion.

14. The semiconductor package of claim 10, wherein the semiconductor device has a first side portion and a second side portion extending along a first horizontal direction, and a third side portion and a fourth side portion extending along a second horizontal direction perpendicular to the first horizontal direction, and
wherein the heat transfer member includes,
a first side heat transfer member at least partially covering the first side portion;
a fourth side heat transfer member at least partially covering the fourth side portion,
wherein the first side heat transfer member and the fourth side heat transfer member of the heat transfer member form an ‘L’ shape when viewed in a plan view such that the heat transfer member covers the first side portion and the fourth side portion of the semiconductor device, and
wherein the heat transfer member exposes the second side portion and the third side portion.

15. The semiconductor package of claim 10, wherein the body portion includes a memory foam core that is resilient, and the thermal conductive film includes a graphite.

16. The semiconductor package of claim 10, further comprising an adhesive member provided between the first portion of the heat slug and the semiconductor device and including thermal interface material (TIM).

17. The semiconductor package of claim 10, wherein the heat transfer member extends above an upper surface of the semiconductor device to define at least a portion of a window at a center portion corresponding to the semiconductor device, and
wherein the semiconductor package further includes an adhesive member provided in the window between the first portion of the heat slug and the semiconductor device and including thermal interface material (TIM).

18. A semiconductor package, comprising:
a package substrate;
a semiconductor device mounted on the package substrate;
a heat slug including a first portion provided on the semiconductor device, a second portion provided on a portion of the package substrate, and an inclined portion connecting the first portion and the second portion;
an adhesive member provided between an upper surface of the semiconductor device and a lower surface of the first portion of the heat slug and including thermal interface material (TIM); and
a heat transfer member disposed in an internal space defined by an upper surface of the package substrate, side portions of the semiconductor device, and an inner surface of the inclined portion, the heat transfer member including a body portion having an elastic material and a thermal conductive film covering the body portion, the heat transfer member being in contact with the semiconductor device and the heat slug,
wherein the heat transfer member provides a first surface in contact with the side portions of the semiconductor device and a second surface in contact with the heat slug.

19. The semiconductor package of claim 18, wherein the heat transfer member includes a thermal foam gasket (TFG).

20. The semiconductor package of claim 18, wherein the heat transfer member is disposed in a compressed state between the package substrate and the heat slug, and surrounding side portions of the semiconductor device.
